(19) United States
(12) Patent Application Publication
(10) Pub. No.: US 2026/0133239 A1
(43) Pub. Date: May 14, 2026

(54) ACTIVE TIME-DOMAIN REFLECTOMETRY MEASUREMENT PROBE AND MEASUREMENT APPLICATION SYSTEM

(71) Applicant: Rohde & Schwarz GmbH & Co. KG, München (DE)

(72) Inventors: Martin PESCHKE, Vaterstetten (DE); Benedikt LIPPERT, München (DE)

(21) Appl. No.: 18/948,088

(22) Filed: Nov. 14, 2024

(51) Int. Cl. G01R 31/11; G01R 31/08

(52) U.S. Cl. CPC G01R 31/11; G01R 31/088

(57) ABSTRACT

The present disclosure provides an active time-domain reflectometry measurement probe comprising at least one oscilloscope interface for coupling to a real-time oscilloscope, a measurement interface for each oscilloscope interface, wherein each measurement interface is coupled to the respective oscilloscope interface and is configured to couple to a device under test, at least one signal generator, wherein the at least one signal generator is coupled to the at least one oscilloscope interface, and the respective measurement interfaces, and wherein the at least one signal generator is configured to generate a test signal and provide the test signal to the measurement interfaces, and a signal monitor configured to transmit the instantaneous voltage at each one of the measurement interfaces to the respective oscilloscope interface. Further, the present disclosure provides a respective measurement application system.

### TECHNICAL FIELD

The disclosure relates to an active time-domain reflectometry measurement probe and to a respective measurement application system.

### BACKGROUND

Although applicable to any type of measurement application device, the present disclosure will mainly be described in conjunction with performing time-domain reflectometry with real-time oscilloscopes.

Time domain reflectometry (TDR) is a fundamental technique employed for analyzing the characteristics of electrical transmission lines or paths by observing reflected waveforms. Specialized instruments designed specifically for reflectometry applications, like Time-domain reflectometers, exist. Other devices, like real-time oscilloscopes, are also capable of performing TDR measurements. However, leveraging real-time oscilloscopes for TDR introduces challenges, particularly in the realm of calibration.

Accurate TDR measurements rely on precise calibration of the measurement system to account for inherent signal delays, impedance variations, and frequency response anomalies within the oscilloscope and associated accessories. Performing calibration on real-time oscilloscopes for TDR applications is often a complex and cumbersome process. This complexity not only increases the time required for setup but also raises the potential for user-induced errors, ultimately compromising measurement accuracy.

Accordingly, there is a need for improving TDR with real-time oscilloscopes.

### SUMMARY

The above stated problem is solved by the features of the independent claims. It is understood, that independent claims of a claim category may be formed in analogy to the dependent claims of another claim category.

Accordingly, it is provided:

An active time-domain reflectometry measurement probe comprising at least one oscilloscope interface for coupling to a real-time oscilloscope, a measurement interface for each oscilloscope interface, wherein each measurement interface is coupled to the respective oscilloscope interface and is configured to couple to a device under test, a signal generator coupled to each measurement interface, wherein the at least one signal generator is configured to generate a test signal and provide the test signal to each measurement interface, and a signal monitor configured to transmit the instantaneous voltage at each one of the measurement interfaces to the respective oscilloscope interface.

Further, it is provided:

A measurement application system comprising a real-time oscilloscope, and an active time-domain reflectometry measurement probe coupled to the real-time oscilloscope, wherein the active time-domain reflectometry measurement probe comprises at least one oscilloscope interface for coupling to a real-time oscilloscope, a measurement interface for each oscilloscope interface, wherein each measurement interface is coupled to the respective oscilloscope interface and is configured to couple to a device under test, a signal generator coupled to each measurement interface, wherein the at least one signal generator is configured to generate a test signal and provide the test signal to each measurement interface, and a signal monitor configured to transmit the instantaneous voltage at each one of the measurement interfaces to the respective oscilloscope interface.

The present disclosure is based on the finding that time-domain reflectometry (TDR) systems with real-time oscilloscopes usually comprise a plurality of different elements, like signal sources, power supplies, cables, splitters, and adapters. The user, consequently, is required to connect all elements, configure all devices and calibrate the system. This is not very user-friendly.

In order to simplify TDR with real-time oscilloscopes, the present disclosure provides the active time-domain reflectometry measurement probe.

The active time-domain reflectometry measurement probe comprises at least one oscilloscope interface and a respective measurement interface for each one of the oscilloscope interfaces. In embodiments, the active time-domain reflectometry measurement probe comprises a single oscilloscope interface with a single respective measurement interface. In other embodiments, the active time-domain reflectometry measurement probe comprises two or more oscilloscope interfaces, each with a respective measurement interface.

The oscilloscope interface is internally communicatively coupled to the respective measurement interface, and allows externally coupling the active time-domain reflectometry measurement probe to a real-time oscilloscope.

The measurement interface allows coupling the active time-domain reflectometry measurement probe to a respective device under test (DUT). It is understood, that the DUT may comprise a single device or a signal path or chain of components that are to be analyzed.

At least one signal generator is provided in the active time-domain reflectometry measurement probe. In embodiments, a single signal generator may be provided for each measurement interface. In addition or as alternative, a single signal generator may be provided for at least two of the measurement interfaces. Respective coupling means, or controllable switching means may be provided for controllably interfacing a single signal generator with multiple measurement interfaces.

The signal generator generates a test signal and provides the test signal to the respective measurement interface or the respective multiple measurement interfaces. The test signal may comprise, but is not limited to, a signal that is required for performing the TDR measurements. Such a signal is provided to the DUT via the measurement interface and reflections of this signal in the signal path that the signal travels in the DUT are analyzed with the real-time oscilloscope that is coupled to the oscilloscope interface of the active time-domain reflectometry measurement probe.

By including the signal generator in the active time-domain reflectometry measurement probe, a user only needs to couple the active time-domain reflectometry measurement probe to the respective real-time oscilloscope, and the DUT without any further cables or other elements being required.

The active time-domain reflectometry measurement probe further comprises a signal monitor. The signal monitor monitors at least the instantaneous voltage at the measurement interface or the multiple measurement interfaces, and provides the monitored instantaneous voltage to the respective oscilloscope interface. The term “instantaneous voltage” in this context refers to the voltage value of an electrical signal at a specific moment in time.

With the signal monitor it is possible to acquire the signal or at least the voltage as provided to the measurement interface in the real-time oscilloscope that is attached to the respective oscilloscope interface of the active time-domain reflectometry measurement probe. The signal monitor, therefore, facilitates comparing the test signal as provided to the DUT with the signal components that are reflected by the signal path that the test signal travels in the DUT.

With the active time-domain reflectometry measurement probe of the present disclosure, the user is provided with a user-friendly, easy-to-setup TDR system for use with real-time oscilloscopes that only requires a few additional components.

In a respective measurement application system the active time-domain reflectometry measurement probe may be coupled to and supplied with electrical power form the real-time oscilloscope. It is understood, that the in the measurement application system, any of the embodiments of the active time-domain reflectometry measurement probe disclosed herein may be used with the real-time oscilloscope.

The active time-domain reflectometry measurement probe may generally be used with any type of measurement application device other than a real-time oscilloscope.

Such measurement application devices may comprise any device that may be used in a measurement application to acquire an input signal or to generate an output signal, or to perform additional or supporting functions in a measurement application. A measurement application device may also comprise or be implemented as program application or program applications, also called measurement program application or measurement program applications, that may be executed on a computer device and that may communicate with other measurement application devices in order to perform a measurement task. A measurement application, also called measurement setup, may e.g., comprise at least one or multiple different measurement application devices for performing electric, magnetic, or electromagnetic measurements, especially on single devices under test. A measurement application device according to the present disclosure may be configured to perform such electric, magnetic, or electromagnetic measurements e.g., in a measurement laboratory or in a production facility in the respective production line on a device under test, DUT. An exemplary measurement application or measurement setup may serve to qualify the single devices under test i.e., to determine the proper electrical operation of the respective devices under test.

Measurement application devices to this end may comprise at least one signal acquisition section for acquiring electric, magnetic, or electromagnetic signals to be measured from a device under test, or at least one signal generation section for generating electric, magnetic, or electromagnetic signals that may be provided to the device under test. Such a signal acquisition section may comprise, but is not limited to, a front-end for acquiring, filtering, and attenuating or amplifying electrical signals. The signal generation section may comprise, but is not limited to, respective signal generators, amplifiers, and filters. In embodiments, the signal acquisition is performed via the signal acquisition section in a wired or contact-based manner or fashion. To this end, a respective measurement probe may be coupled to the measurement application device via a respective cable. In embodiments, the signal generation and emission is performed via the signal generation section in a wired or contact-based manner or fashion. To this end, a respective signal output probe may be coupled to the measurement application device via a respective cable, or the signal may be output directly via the cable e.g., to a device under test.

Further, when acquiring signals, measurement application devices may comprise a signal processing section that may process the acquired signals. Processing may comprise converting the acquired signals from analog to digital signals, and any other type of digital signal processing, for example, converting signals from the time-domain into the frequency-domain.

The measurement application devices may also comprise a user interface to display the acquired signals to a user and allow a user to control the measurement application devices. Of course, a housing may be provided that comprises the elements of the measurement application device. It is understood, that further elements, like power supply circuitry, and communication interfaces may be provided.

A measurement application device may be a stand-alone device that may be operated without any further element in a measurement application to perform tests on a device under test. Of course, communication capabilities may also be provided for the measurement application device to interact with other measurement application devices.

A measurement application device may comprise, for example, a signal acquisition device e.g., an oscilloscope, especially a digital oscilloscope, a spectrum analyzer, or a vector network analyzer. Such a measurement application device may also comprise a signal generation device e.g., a signal generator, especially an arbitrary signal generator, also called arbitrary waveform generator, or a vector signal generator. Further possible measurement application devices comprise devices like calibration standards, or measurement probe tips.

Of course, at least some of the possible functions, like signal acquisition and signal generation, may be combined in a single measurement application device.

In embodiments, the measurement application device may comprise pure data acquisition devices that are capable of acquiring an input signal and of providing the acquired input signal as digital input signal to a respective data storage or application server. Such pure data acquisition devices not necessarily comprise a user interface or display. Instead, such pure data acquisition devices may be controlled remotely e.g., via a respective data interface, like a network interface or a USB interface. The same applies to pure signal generation devices that may generate an output signal without comprising any user interface or configuration input elements. Instead, such signal generation devices may be operated remotely via a data connection.

Further embodiments of the present disclosure are subject of the further dependent claims and of the following description, referring to the drawings.

In the following, the dependent claims referring directly or indirectly to claim 1 are described in more detail. For the avoidance of doubt, the features of the dependent claims relating to independent claim 1 can be combined in all variations with each other and the disclosure of the description is not limited to the claim dependencies as specified in the claim set. Further, the features of the dependent claims referring to independent claim 1 may be combined with any of the features of the other independent claims or the dependent claims relating to any one of the other independent claims. In a respective method, respective method steps may perform the function of the respective apparatus elements, and in a respective apparatus, respective apparatus elements may perform the respective method steps.

In an embodiment, which can be combined with all other embodiments mentioned above or below, the oscilloscope interface may comprise at least one coaxial connector.

A coaxial connector is a well known type of connector of low complexity that may be used with a variety of different real-time oscilloscopes. Using such a coaxial connector, consequently, allows using the active time-domain reflectometry measurement probe with any one of such real-time oscilloscopes.

When providing a single coaxial connector, the oscilloscope interface may be called a single-ended interface. With two coaxial connectors, the oscilloscope interface may be called a differential interface, or also a double-ended interface.

The active time-domain reflectometry measurement probe according to claim 1, wherein the oscilloscope interface comprises an active probe interface configured to transmit at least one of at least one measurement signal, at least one digital data signal, and electrical supply power.

The oscilloscope interface may comprise a so-called active probe interface. This active probe interface may be provided as alternative to or in addition to the coaxial connector. In embodiments, the active probe interface may comprise a coaxial connector in combination with further connectors for digital data transmission and power supply.

The active probe interface generally serves as a kind of multi-functional interface that allows transmitting measurement signals of the respective measurement application, as well as other additional signals, like control signals and power supply signals, between the real-time oscilloscope and the active time-domain reflectometry measurement probe.

In an embodiment, which can be combined with all other embodiments mentioned above or below, the active probe interface may be configured to receive electrical supply power and supply the at least on signal generator with the electrical supply power.

The active probe interface may receive electrical supply power from the real-time oscilloscope via the active probe interface. The received electrical supply power may be distributed internally in the active time-domain reflectometry measurement probe to any element or device that requires electrical supply power to operate. Therefore, any other element of the active time-domain reflectometry measurement probe in addition to the signal generator may also be provided with electrical supply power by the active probe interface.

By supplying the signal generator with electrical supply power via the active probe interface, after connecting the active time-domain reflectometry measurement probe to the real-time oscilloscope, the active time-domain reflectometry measurement probe may already be in a fully functional state, and respective measurements may be initiated immediately.

In another embodiment, which can be combined with all other embodiments mentioned above or below, the active probe interface may be configured to at least one of receive an incoming digital data signal from the real-time oscilloscope, and forward the received incoming digital data signal internally in the active time-domain reflectometry measurement probe, and receive an outgoing digital data signal from a component of the active time-domain reflectometry measurement probe, and forward the outgoing digital data signal to the real-time oscilloscope.

Providing the active time-domain reflectometry measurement probe with the ability to receive the incoming digital data signal allows controlling elements of the active time-domain reflectometry measurement probe with an external source, like the real-time oscilloscope.

The incoming digital data signal may, e.g., be generated in the real-time oscilloscope to control the active time-domain reflectometry measurement probe, e.g., to set signal levels and a repetition frequency for the test signal. A user, consequently, may operate and control the complete TDR system from the real-time oscilloscope only, instead of having to adjust different components, like an external signal generator.

The outgoing digital data signal may be used to provide any relevant data from the active time-domain reflectometry measurement probe to the real-time oscilloscope. The active time-domain reflectometry measurement probe may, e.g., confirm reception and processing of the incoming digital data signal. The active time-domain reflectometry measurement probe may also provide status or error data to the real-time oscilloscope via the outgoing digital data signal.

In a further embodiment, which can be combined with all other embodiments mentioned above or below, the measurement interface may comprise at least one coaxial connector.

As with the oscilloscope interface, using a coaxial connector in the measurement interface allows using the active time-domain reflectometry measurement probe with other standard equipment, like coaxial cables and connectors.

When providing a single coaxial connector, the measurement interface may be called a single-ended interface. With two coaxial connectors, the measurement interface may be called a differential interface, or also a double-ended interface.

In another embodiment, which can be combined with all other embodiments mentioned above or below, the measurement interface may comprise at least one pin.

The term “pin” in this regard may refer to a hand-held conductive pin or needle shaped device that a user may hold in his hand to manually contact different probing points in the DUT.

Providing one or more pins in the measurement interface allows simply browsing different signal acquisition points in the DUT.

In embodiments, the measurement interface may comprise a combination of at least one coaxial connector and at least one pin.

Again, when providing a single pin, the measurement interface may be called a single-ended interface. With two pins, the measurement interface may be called a differential interface, or also a double-ended interface.

In an embodiment, which can be combined with all other embodiments mentioned above or below, the signal generator may comprise at least one of a step generator, a pulse generator, an arbitrary waveform generator, a broadband signal generator, and a sine wave signal generator.

By providing different types of waveform generators in the signal generator, it is possible to adapt the test signal to a plurality of different measurement applications.

In another embodiment, which can be combined with all other embodiments mentioned above or below, the signal monitor may comprise at least one of a power splitter, an active buffer amplifier, and a microwave coupler.

Using a power splitter as the signal monitor allows transmitting the instantaneous voltage with a very high bandwidth. In contrast, with an active buffer amplifier instantaneous voltages with a lower signal or voltage level may be transmitted. Compared to the power splitter, the microwave coupler will exhibit lower attenuation or losses of the signal to be transmitted.

In a further embodiment, which can be combined with all other embodiments mentioned above or below, the measurement interface may comprise two signal ports, wherein the signal generator may comprise a single differential pulse generator.

With a differential pulse generator an active time-domain reflectometry measurement probe of low complexity may be provided, since the differential output pulse may be generated by a single integrated device.

The differential pulse generator may be coupled to two coaxial connectors or pins of the measurement interface in order to output a differential pulse signal. The active time-domain reflectometry measurement probe in this case is used as an active TDR probe with differential output or differential pulse generator.

In an embodiment, which can be combined with all other embodiments mentioned above or below, the measurement interface may comprise two signal ports, and the signal generator may comprise two single-ended pulse generators.

With two single-ended pulse generators for forming a differential signal generator, it is possible to configure and control each one of the single-ended pulse generators separately. Such a configuration, therefore, increases the flexibility of the active time-domain reflectometry measurement probe.

In another embodiment with two single-ended pulse generators, which can be combined with all other embodiments mentioned above or below, the active time-domain reflectometry measurement probe may further comprise a skew adjuster that is coupled to the two single-ended pulse generators, and that is configured to adjust the skew between output signals of the two single-ended pulse generators.

With two single-ended pulse generators, the skew adjuster may be used to adjust any misalignment of the output signals of the two single-ended pulse generators.

In an embodiment, which can be combined with all other embodiments mentioned above or below, the active time-domain reflectometry measurement probe may further comprise a data memory configured to at least store calibration data for the active time-domain reflectometry measurement probe.

The data memory may comprise a dedicated data interface to provide the calibration data, e.g., to the real-time oscilloscope. In embodiments with an active probe interface, the data memory may be coupled to the active probe interface to communicate with the real-time oscilloscope.

The calibration data may be provided during an end-of-line calibration that may be performed during the production of the active time-domain reflectometry measurement probe. The calibration data may also be provided or updated, e.g., via the real-time oscilloscope or during a service of the active time-domain reflectometry measurement probe. In embodiments, the calibration data or any other data required for operating the active time-domain reflectometry measurement probe may be provided from the data memory to the real-time oscilloscope, or may be received from the real-time oscilloscope and stored in the data memory.

In embodiments, the active probe interface may comprise respective communication controllers for a communication system used in the active probe interface. The data memory may be coupled to such a communication controller in order to transmit data to and from the data memory.

The data stored in the data memory may comprise, e.g., the pulse shape of the test signal as provided by the signal generator, or the spectrum of the test signal as provided by the signal generator, or an incident signal.

In a further embodiment, which can be combined with all other embodiments mentioned above or below, the active time-domain reflectometry measurement probe may further comprise at least one coaxial cable that is arranged between the signal monitor and the measurement interface and that transmits the instantaneous voltage from the signal monitor to the oscilloscope interface.

Embodiments of the active time-domain reflectometry measurement probe with a signal generator and measurement interface that are both remote to the oscilloscope interface, a cable may be used to couple the measurement interface, and the signal generator to the oscilloscope interface.

In a further embodiment, which can be combined with all other embodiments mentioned above or below, the active time-domain reflectometry measurement probe may further comprise at least one hybrid cable that is arranged between the signal monitor and the measurement interface and that at least transmits the instantaneous voltage from the signal monitor to the oscilloscope interface, control signals from the oscilloscope interface to at least one of the signal monitor and the signal generator, and electrical supply power from the oscilloscope interface to at least one of the signal monitor, and the signal generator.

With the hybrid cable, it is possible to not only transmit the instantaneous voltage from the signal monitor to the oscilloscope interface, but to also transmit control signals and electrical supply power to the signal generator or any other element of the active time-domain reflectometry measurement probe.

In a further embodiment, which can be combined with all other embodiments mentioned above or below, the active time-domain reflectometry measurement probe may further comprise a housing that accommodates the at least one oscilloscope interface, the respective measurement interfaces, the at least one signal generator, and the signal monitor.

With the housing, the active time-domain reflectometry measurement probe may be provided as fully integrated element or device that only needs to be coupled to a real-time oscilloscope and the respective DUT in order to perform the TDR measurements. Of course, the respective connectors and interfaces may be provided in the housing.

The Housing may comprise a single element or a group of elements, like a measurement-device-facing housing part, and a DUT-facing housing part that may be coupled to each other via a cable, like an active probe interface.

### BRIEF DESCRIPTION OF THE DRAWINGS

For a more complete understanding of the present disclosure and advantages thereof, reference is now made to the following description taken in conjunction with the accompanying drawings. The disclosure is explained in more detail below using exemplary embodiments which are specified in the schematic figures of the drawings, in which:

FIG. 1 shows a block diagram of an embodiment of an active time-domain reflectometry measurement probe according to the present disclosure;

FIG. 2 shows a block diagram of another embodiment of an active time-domain reflectometry measurement probe according to the present disclosure;

FIG. 3 shows a block diagram of another embodiment of an active time-domain reflectometry measurement probe according to the present disclosure;

FIG. 4 shows a block diagram of another embodiment of an active time-domain reflectometry measurement probe according to the present disclosure;

FIG. 5 shows a block diagram of another embodiment of an active time-domain reflectometry measurement probe according to the present disclosure;

FIG. 6 shows a block diagram of another embodiment of an active time-domain reflectometry measurement probe according to the present disclosure;

FIG. 7 shows a block diagram of another embodiment of an active time-domain reflectometry measurement probe according to the present disclosure;

FIG. 8 shows a block diagram of another embodiment of an active time-domain reflectometry measurement probe according to the present disclosure; and

FIG. 9 shows a block diagram of an embodiment of a measurement application system according to the present disclosure.

FIG. 10 shows a block diagram of a real-time oscilloscope according to the present disclosure.

In the figures like reference signs denote like elements unless stated otherwise.

### DETAILED DESCRIPTION OF THE DRAWINGS

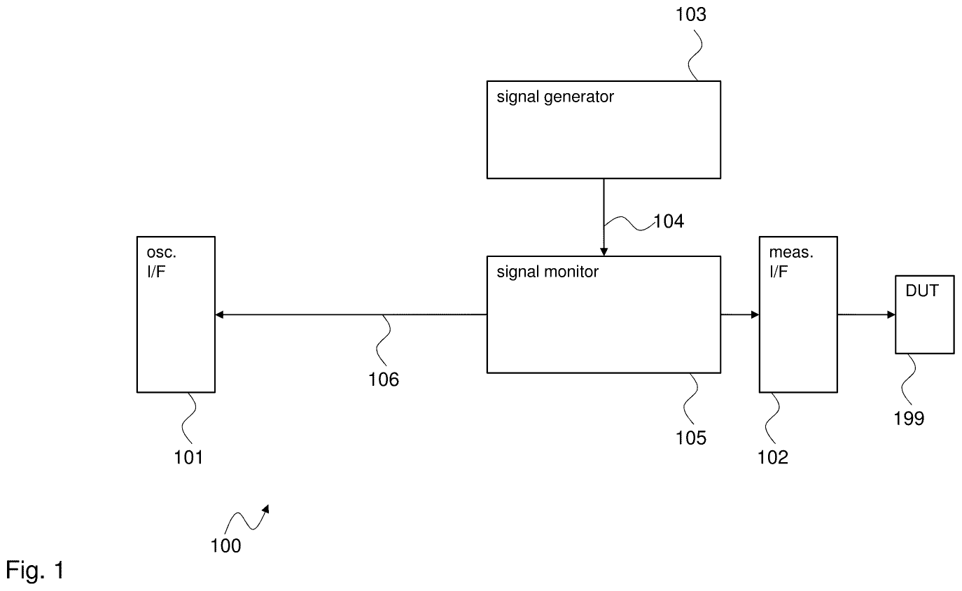

FIG. 1 shows a block diagram of an active time-domain reflectometry measurement probe 100. The active time-domain reflectometry measurement probe 100 comprises an oscilloscope interface 101 for coupling to a real-time oscilloscope, and a measurement interface 102 that may be coupled to a device under test, DUT, 199. Further, the active time-domain reflectometry measurement probe 100 comprises a signal generator 103 and a signal monitor 105. The signal generator 103 is coupled to the signal monitor 105, and the signal monitor 105 is exemplarily arranged between the oscilloscope interface 101, and the measurement interface 102. The explanations provided herein for any embodiment of the active time-domain reflectometry measurement probe apply mutatis mutandis to active time-domain reflectometry measurement probe 100.

While the active time-domain reflectometry measurement probe 100 comprises a single oscilloscope interface 101 with a single respective measurement interface 102, in other embodiments, the active time-domain reflectometry measurement probe may comprise any number of oscilloscope interfaces with respective measurement interfaces.

The signal generator 103 is coupled to the measurement interface and generates a test signal 104 for outputting to the DUT 199. In embodiments with more than one measurement interface 102, a signal generator 103 may be provided for each one of the measurement interfaces 102, or a single signal generator 103 may generate multiple test signals 104, e.g., one for each measurement interface 102.

The signal monitor 105 transmits the instantaneous voltage 106 at the measurement interface 102 to the oscilloscope interface 101. The instantaneous voltage 106 represents the generates a test signal 104 as input into the DUT 199. By providing this instantaneous voltage 106 via the oscilloscope interface 101 to a real-time oscilloscope, it is possible to compare the signal that is input into the signal path of the DUT 199 with the reflections that are returned from that signal path.

The signal monitor 105 may comprise any adequate element that allows picking up the instantaneous voltage 106 at the measurement interface 102. Possible implementations of the signal monitor 105 comprise, but are not limited to, a power splitter, an active buffer amplifier, and a microwave coupler.

In the exemplary embodiment of the active time-domain reflectometry measurement probe 100, the signal monitor 105 is arranged between the oscilloscope interface 101, and the measurement interface 102. In other embodiments, the signal monitor 105 may be arranged or configured differently. The signal generator 103 may, e.g., be coupled directly to the measurement interface 102, and the signal generator 103 may pick up the instantaneous voltage 106 from this direct connection.

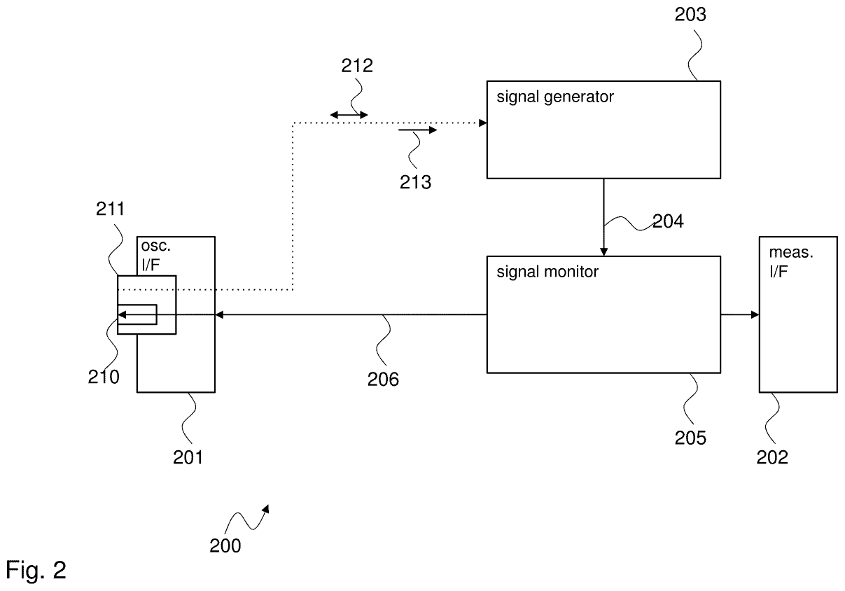

FIG. 2 shows a block diagram of an active time-domain reflectometry measurement probe 200. The active time-domain reflectometry measurement probe 200 is based on the active time-domain reflectometry measurement probe 100. Therefore, the active time-domain reflectometry measurement probe 200 comprises an oscilloscope interface 201 for coupling to a real-time oscilloscope, and a measurement interface 202 that may be coupled to a device under test, DUT. Further, the active time-domain reflectometry measurement probe 200 comprises a signal generator 203 and a signal monitor 205. The signal generator 203 is coupled to the signal monitor 205, and the signal monitor 205 is exemplarily arranged between the oscilloscope interface 201, and the measurement interface 202. The explanations provided herein for any embodiment of the active time-domain reflectometry measurement probe apply mutatis mutandis to active time-domain reflectometry measurement probe 200.

In the active time-domain reflectometry measurement probe 200, the oscilloscope interface 201 comprises a coaxial connector 210 that is arranged in an optional active probe interface 211. In embodiments, the oscilloscope interface 201 may only comprise the coaxial connector 210 for signal transmission. A dedicated coaxial connector 210 may be provided for every measurement interface 202, and/or a switching matrix may be provided for coupling a single coaxial connector 210 to different measurement interfaces 202.

The coaxial connector 210 serves for transmitting measurement signals, like the instantaneous voltage 206 and the reflections of the test signal 204 to a connected real-time oscilloscope.

The active probe interface 211 may comprise further connectors and interfaces, like data interfaces, and power supply interfaces. With the active probe interface 211 electrical supply power 213, and digital data signals 212 may be provided to the active time-domain reflectometry measurement probe 200, e.g., for powering and controlling the signal generator 203. Although not explicitly shown, it is understood, that any other component of the active time-domain reflectometry measurement probe 200 may also be provided with electrical supply power 213, and digital data signals 212.

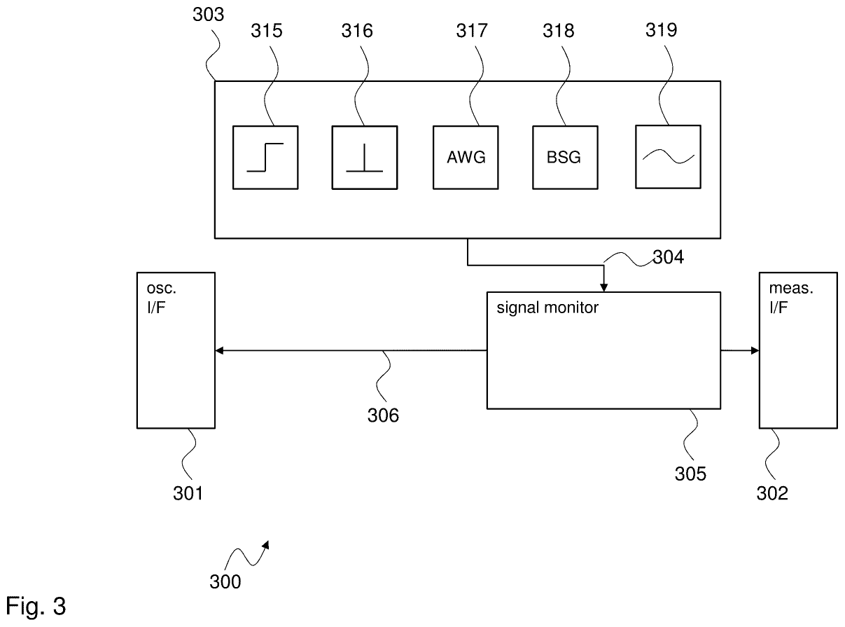

FIG. 3 shows a block diagram of an active time-domain reflectometry measurement probe 300. The active time-domain reflectometry measurement probe 300 is based on the active time-domain reflectometry measurement probe 100. Therefore, the active time-domain reflectometry measurement probe 300 comprises an oscilloscope interface 301 for coupling to a real-time oscilloscope, and a measurement interface 302 that may be coupled to a device under test, DUT. Further, the active time-domain reflectometry measurement probe 300 comprises a signal generator 303 and a signal monitor 305. The signal generator 303 is coupled to the signal monitor 305, and the signal monitor 305 is exemplarily arranged between the oscilloscope interface 301, and the measurement interface 302. The explanations provided herein for any embodiment of the active time-domain reflectometry measurement probe apply mutatis mutandis to active time-domain reflectometry measurement probe 300.

In the active time-domain reflectometry measurement probe 300, the signal monitor 305 is exemplarily shown to comprise five different signal generators without being limited to a step generator 315, a pulse generator 316, an arbitrary waveform generator 317, a broadband signal generator 318, and a sine wave signal generator 319.

In embodiments, the signal monitor 305 may comprise only a selection or sub-set of the shown signal generators 315-319.

Although not explicitly shown, it is understood, that the signal generators 315-319 may comprise respective control logic, that allows controlling the signal generators 315-319 via an active probe interface of the active time-domain reflectometry measurement probe 300.

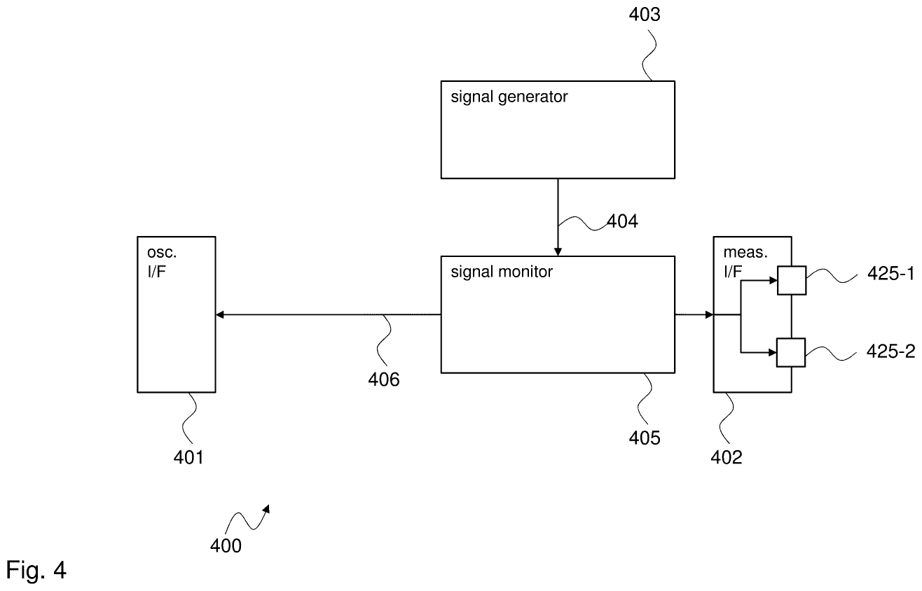

FIG. 4 shows a block diagram of an active time-domain reflectometry measurement probe 400. The active time-domain reflectometry measurement probe 400 is based on the active time-domain reflectometry measurement probe 100. Therefore, the active time-domain reflectometry measurement probe 400 comprises an oscilloscope interface 401 for coupling to a real-time oscilloscope, and a measurement interface 402 that may be coupled to a device under test, DUT. Further, the active time-domain reflectometry measurement probe 400 comprises a signal generator 403 and a signal monitor 405. The signal generator 403 is coupled to the signal monitor 405, and the signal monitor 405 is exemplarily arranged between the oscilloscope interface 401, and the measurement interface 402. The explanations provided herein for any embodiment of the active time-domain reflectometry measurement probe apply mutatis mutandis to active time-domain reflectometry measurement probe 400.

In the active time-domain reflectometry measurement probe 400, the measurement interface 402 comprises two signal ports 425-1, 425-2. Such a measurement interface 402 is also called a differential measurement interface 402 that is capable of providing differential signals to a DUT.

In embodiments, the two signal ports 425-1, 425-2 may comprise at least one of coaxial connectors and pins.

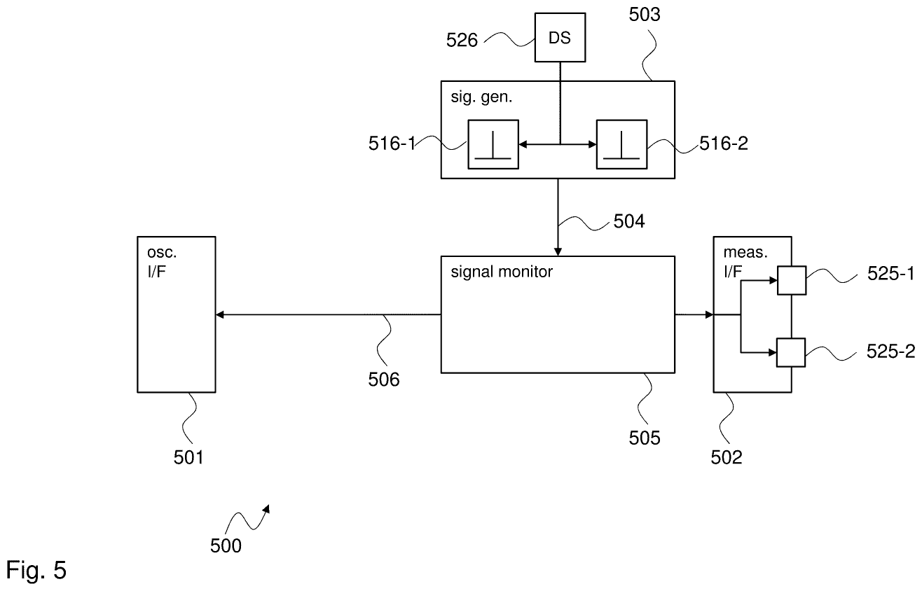

In the active time-domain reflectometry measurement probe 400, the signal generator 403 may be a differential signal generator 403. As will be shown below with regard to FIG. 5, the signal generator may also comprise two single-ended signal generators.

FIG. 5 shows a block diagram of an active time-domain reflectometry measurement probe 500. The active time-domain reflectometry measurement probe 500 is based on the active time-domain reflectometry measurement probe 400. Therefore, the active time-domain reflectometry measurement probe 500 comprises an oscilloscope interface 501 for coupling to a real-time oscilloscope, and a measurement interface 502 that may be coupled to a device under test, DUT. Further, the active time-domain reflectometry measurement probe 500 comprises a signal generator 503 and a signal monitor 505. The signal generator 503 is coupled to the signal monitor 505, and the signal monitor 505 is exemplarily arranged between the oscilloscope interface 501, and the measurement interface 502. The measurement interface 502 comprises two signal ports 525-1, 525-2. Such a measurement interface 502 is also called a differential measurement interface 502 that is capable of providing differential signals to a DUT. The explanations provided herein for any embodiment of the active time-domain reflectometry measurement probe apply mutatis mutandis to active time-domain reflectometry measurement probe 500.

In the active time-domain reflectometry measurement probe 500, the signal generator 503 exemplarily comprises to single-ended pulse generators 516-1, 516-2. It is understood, that other types of signal generators, e.g., as shown in FIG. 3, may also be used.

The active time-domain reflectometry measurement probe 500 further comprises an optional skew adjuster 526 that is coupled to the single-ended pulse generators 516-1, 516-2 for controlling the skew between the signals provided by the single-ended pulse generators 516-1, 516-2. Although not explicitly shown, the skew adjuster 526 may be digitally coupled to a real-time oscilloscope via an active probe interface as, e.g., shown in FIG. 2, for controlling the skew adjuster 526, and for providing feedback data from the skew adjuster 526 to the real-time oscilloscope.

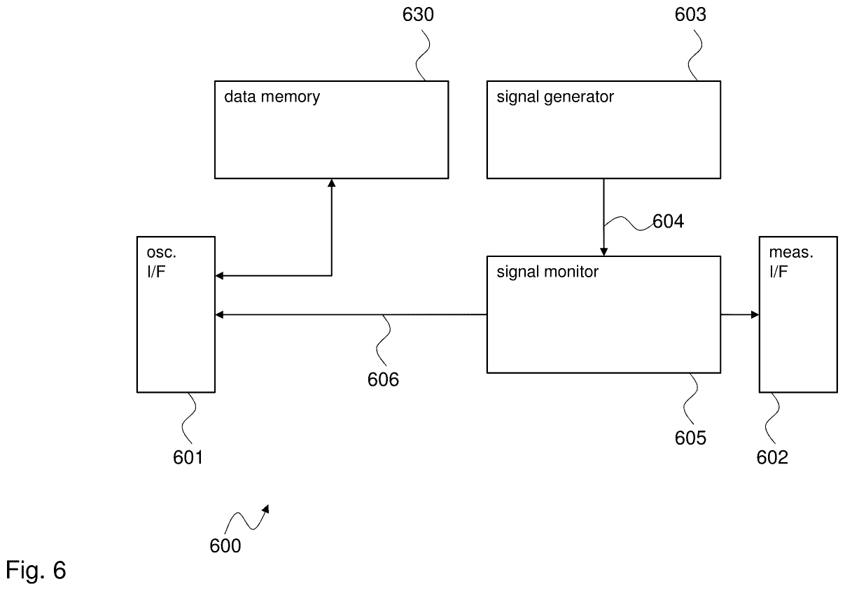

FIG. 6 shows a block diagram of an active time-domain reflectometry measurement probe 600. The active time-domain reflectometry measurement probe 600 is based on the active time-domain reflectometry measurement probe 100. Therefore, the active time-domain reflectometry measurement probe 600 comprises an oscilloscope interface 601 for coupling to a real-time oscilloscope, and a measurement interface 602 that may be coupled to a device under test, DUT. Further, the active time-domain reflectometry measurement probe 600 comprises a signal generator 603 and a signal monitor 605. The signal generator 603 is coupled to the signal monitor 605, and the signal monitor 605 is exemplarily arranged between the oscilloscope interface 601, and the measurement interface 602. The explanations provided herein for any embodiment of the active time-domain reflectometry measurement probe apply mutatis mutandis to active time-domain reflectometry measurement probe 600.

The active time-domain reflectometry measurement probe 600 further comprises a data memory 630. The data memory 630 may serve for storing calibration data for the active time-domain reflectometry measurement probe 600. Such calibration data may be provided to the data memory 630 in an end-of-line calibration during manufacturing of the active time-domain reflectometry measurement probe 600 or at later stages during a service of the active time-domain reflectometry measurement probe 600, or via a real-time oscilloscope that performs a calibration of the active time-domain reflectometry measurement probe 600. The data memory 630 may, e.g., be used with an active probe interface as shown in FIG. 2. This allows a real-time oscilloscope to read the data from the data memory 630 and to use the calibration data for a measurement.

The data memory 630 may also be coupled to any other element of the active time-domain reflectometry measurement probe 600, like the signal generator 603, the signal monitor 605, and the measurement interface 602, and may provide configuration parameters or configuration data to any one of these elements.

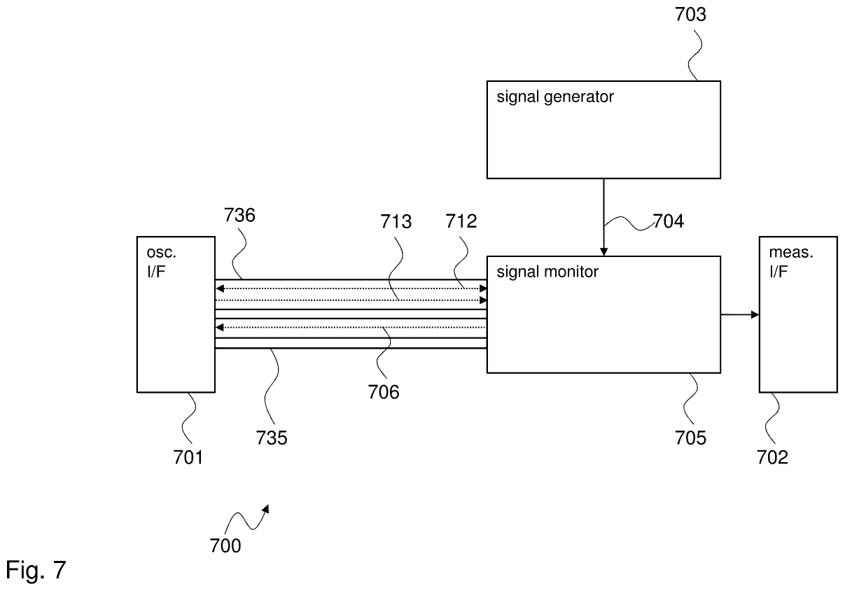

FIG. 7 shows a block diagram of an active time-domain reflectometry measurement probe 700. The active time-domain reflectometry measurement probe 700 is based on the active time-domain reflectometry measurement probe 100. Therefore, the active time-domain reflectometry measurement probe 700 comprises an oscilloscope interface 701 for coupling to a real-time oscilloscope, and a measurement interface 702 that may be coupled to a device under test, DUT. Further, the active time-domain reflectometry measurement probe 700 comprises a signal generator 703 and a signal monitor 705. The signal generator 703 is coupled to the signal monitor 705, and the signal monitor 705 is exemplarily arranged between the oscilloscope interface 701, and the measurement interface 702. The explanations provided herein for any embodiment of the active time-domain reflectometry measurement probe apply mutatis mutandis to active time-domain reflectometry measurement probe 700.

In the active time-domain reflectometry measurement probe 700, the oscilloscope interface 701, and the signal monitor 705 are coupled to each other via a coaxial cable 735 that may optionally be embedded in a hybrid cable 736. The oscilloscope interface 701, and the coaxial cable 735, or hybrid cable 736, as well as the signal monitor 705 may be integrally coupled to each other, e.g., by a common or fixed enclosure of these elements.

Providing the cables 735, 736 between the oscilloscope interface 701, and the signal monitor 705 allows placing the oscilloscope interface 701 remotely from the other elements of the active time-domain reflectometry measurement probe 700.

While the coaxial cable 735 may serve to transmit the instantaneous voltage 706 to the oscilloscope interface 701, the hybrid cable 736 may further comprise data lines and power supply lines to exchange digital data between a real-time oscilloscope, and the other elements of the active time-domain reflectometry measurement probe 700, like the signal generator 703.

It is understood, that the coaxial cable 735, or the hybrid cable 736 may also be directly coupled to other elements, like the signal generator 703, and/or the measurement interface 702.

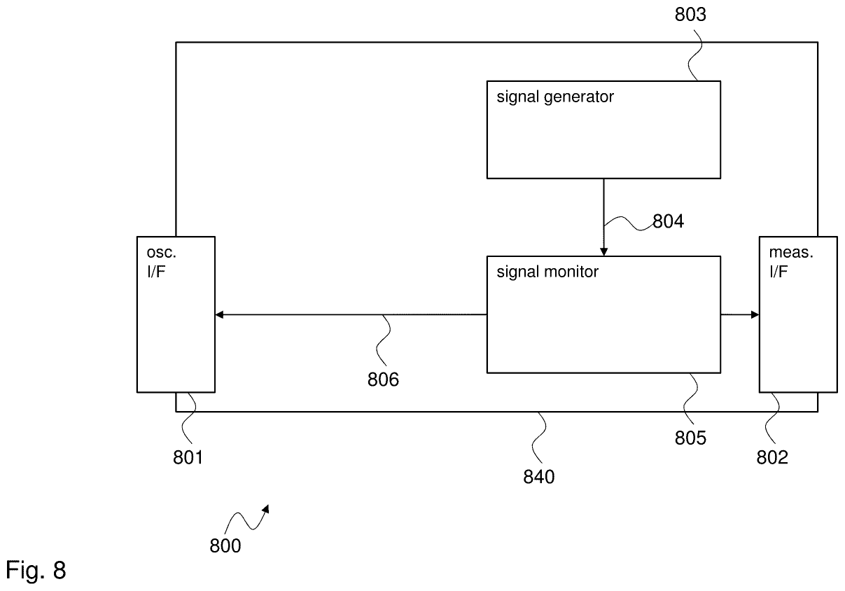

FIG. 8 shows a block diagram of an active time-domain reflectometry measurement probe 800. The active time-domain reflectometry measurement probe 800 is based on the active time-domain reflectometry measurement probe 100. Therefore, the active time-domain reflectometry measurement probe 800 comprises an oscilloscope interface 801 for coupling to a real-time oscilloscope, and a measurement interface 802 that may be coupled to a device under test, DUT. Further, the active time-domain reflectometry measurement probe 800 comprises a signal generator 803 and a signal monitor 805. The signal generator 803 is coupled to the signal monitor 805, and the signal monitor 805 is exemplarily arranged between the oscilloscope interface 801, and the measurement interface 802. The explanations provided herein for any embodiment of the active time-domain reflectometry measurement probe apply mutatis mutandis to active time-domain reflectometry measurement probe 800.

The active time-domain reflectometry measurement probe 800 further comprises a housing 840 that encloses all elements of the active time-domain reflectometry measurement probe 800. The oscilloscope interface 801, and the measurement interface 802 may of course at least comprise connectors that allow contacting the active time-domain reflectometry measurement probe 800 with the outside, e.g., a real-time oscilloscope or a DUT.

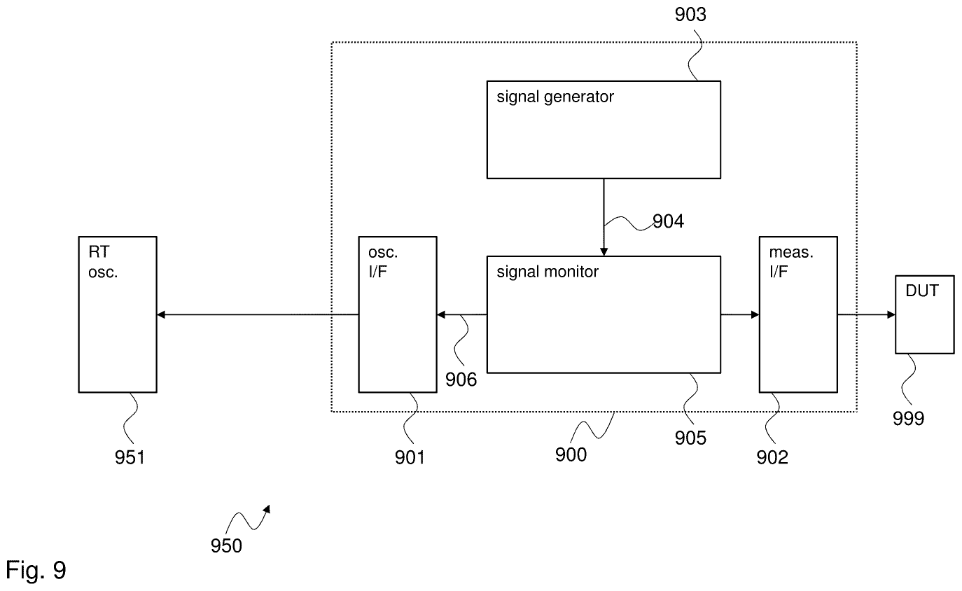

FIG. 9 shows a block diagram of a measurement application system 950. The measurement application system 950 comprises a active time-domain reflectometry measurement probe 900 that is coupled to a real-time oscilloscope 951, and a DUT 999.

It is understood, that any of the embodiments of the active time-domain reflectometry measurement probe may be used with the real-time oscilloscope 951, and that the real-time oscilloscope 951 may comprise a coaxial-based interface to the active time-domain reflectometry measurement probe 900, or an active probe interface to the active time-domain reflectometry measurement probe 900.

The measurement interface 902 may comprise a single-ended or differential interface to the DUT 999.

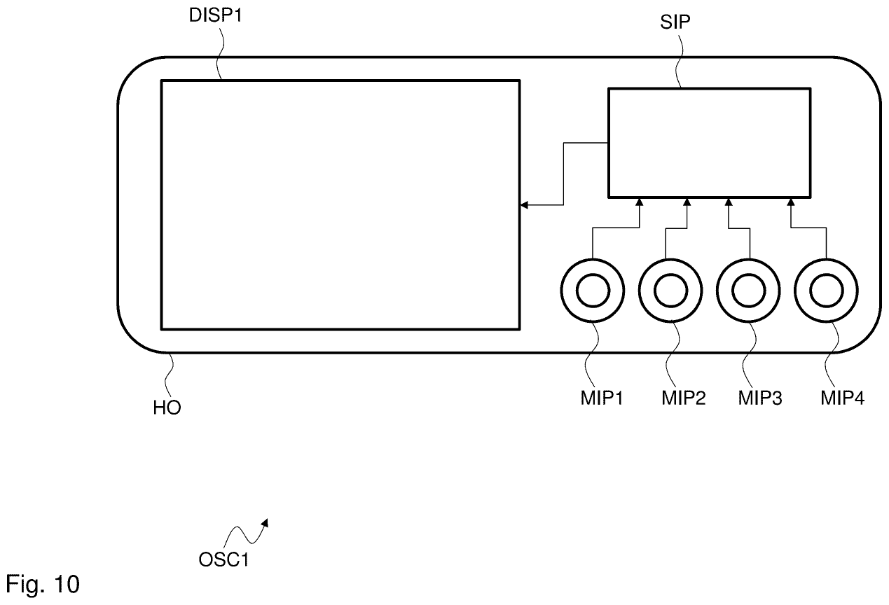

FIG. 10 shows a block diagram of a real-time oscilloscope OSC1 that may be used in an embodiment of a measurement application system according to the present disclosure.

The oscilloscope OSC1 comprises a housing HO that accommodates four measurement inputs MIP1, MIP2, MIP3, MIP4 that are coupled to a signal processor SIP for processing any measured signals. The signal processor SIP is coupled to a display DISP1 for displaying the measured signals to a user.

Although not explicitly shown, it is understood, that the oscilloscope OSC1 may also comprise signal outputs. Such signal outputs may for example serve to output calibration signals. Such calibration signals allow calibrating the measurement setup prior to performing any measurement. The process of calibrating and correcting any measurement signals based on the calibration may also be called de-embedding and may comprise applying respective algorithms on the measured signals.

In the oscilloscope OSC1 the signal processor SIP or an additional processing element may perform the function of communicating with the active time-domain reflectometry measurement probe, especially via an active probe interface. Of course, a communication interface may be provided in the oscilloscope OSC1 for communication with other measurement application devices.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their broadest reasonable constructions and their ordinary meanings as understood by those knowledgeable in the technologies described herein unless an explicit indication to the contrary in made herein. In particular, use of the singular articles such as “a,” “the,” “said,” etc. should be read to recite one or more of the indicated elements unless a claim recites an explicit limitation to the contrary.

The abstract of the disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

### LIST OF REFERENCE SIGNS

100, 200, 300, 400, 500, 600 active time-domain reflectometry measurement probe
700, 800, 900 active time-domain reflectometry measurement probe
101, 201, 301, 401, 501, 601, 701 oscilloscope interface
801, 901 oscilloscope interface
102, 202, 302, 402, 502, 602, 702 measurement interface
802, 902 measurement interface
103, 203, 303, 403, 503, 603, 703 signal generator
803, 903 signal generator
104, 204, 304, 404, 504, 604, 704 test signal
804, 904 test signal
105, 205, 305, 405, 505, 605, 705 signal monitor
805, 905 signal monitor
106, 206, 306, 406, 506, 606, 706 instantaneous voltage
806, 906 instantaneous voltage
210 coaxial connector
211 active probe interface
212, 712 digital data signal
213, 713 electrical supply power
315 step generator
316, 516-1, 516-2 pulse generator
317 arbitrary waveform generator
318 broadband signal generator
319 sine wave signal generator
425-1, 425-2, 525-1, 525-2 signal port
526 skew adjuster
630 data memory
735 coaxial cable
736 hybrid cable
840 housing
950 measurement application system
951 real-time oscilloscope
199, 999 device under test
OSC1 oscilloscope
HO housing
MIP1, MIP2, MIP3, MIP4 measurement input
SIP signal processing
DISP1 display

1. An active time-domain reflectometry measurement probe comprising:
at least one oscilloscope interface for coupling to a real-time oscilloscope;
a measurement interface for each oscilloscope interface, wherein each measurement interface is coupled to the respective oscilloscope interface and is configured to couple to a device under test;
a signal generator coupled to each measurement interface, wherein the signal generator is configured to generate a test signal and provide the test signal to each measurement interface; and
a signal monitor configured to transmit an instantaneous voltage at each one of the measurement interfaces to the respective oscilloscope interface.

2. The active time-domain reflectometry measurement probe according to claim 1, wherein the oscilloscope interface comprises at least one coaxial connector.

3. The active time-domain reflectometry measurement probe according to claim 1, wherein the oscilloscope interface comprises an active probe interface configured to transmit at least one of: at least one measurement signal, at least one digital data signal, or electrical supply power.

4. The active time-domain reflectometry measurement probe according to claim 3, wherein the active probe interface is configured to receive electrical supply power and supply the at least on signal generator with the electrical supply power.

5. The active time-domain reflectometry measurement probe according to claim 3, wherein the active probe interface is configured to at least one of:
receive an incoming digital data signal from the real-time oscilloscope, and forward the received incoming digital data signal internally in the active time-domain reflectometry measurement probe; or
receive an outgoing digital data signal from a component of the active time-domain reflectometry measurement probe, and forward the outgoing digital data signal to the real-time oscilloscope.

6. The active time-domain reflectometry measurement probe according to claim 1, wherein the measurement interface comprises at least one coaxial connector.

7. The active time-domain reflectometry measurement probe according to claim 1, wherein the measurement interface comprises at least one pin.

8. The active time-domain reflectometry measurement probe according to claim 1, wherein the signal generator comprises at least one of the following:
a step generator;
a pulse generator;
an arbitrary waveform generator;
a broadband signal generator; or
a sine wave signal generator.

9. The active time-domain reflectometry measurement probe according to claim 1, wherein the signal monitor comprises at least one of:
a power splitter;
an active buffer amplifier; or
a microwave coupler.

10. The active time-domain reflectometry measurement probe according to claim 1, wherein the measurement interface comprises two signal ports; and wherein the signal generator comprises a single differential pulse generator.

11. The active time-domain reflectometry measurement probe according to claim 1, wherein the measurement interface comprises two signal ports; and wherein the signal generator comprises two single-ended pulse generators.

12. The active time-domain reflectometry measurement probe according to claim 11, further comprising a skew adjuster that is coupled to the two single-ended pulse generators, and is configured to adjust the skew between output signals of the two single-ended pulse generators.

13. The active time-domain reflectometry measurement probe according to claim 1, further comprising a data memory configured to at least store calibration data for the active time-domain reflectometry measurement probe.

14. The active time-domain reflectometry measurement probe according to claim 1, further comprising at least one coaxial cable that is arranged between the signal monitor and the measurement interface and transmits the instantaneous voltage from the signal monitor to the oscilloscope interface.

15. The active time-domain reflectometry measurement probe according to claim 1, further comprising at least one hybrid cable that is arranged between the signal monitor and the measurement interface and that at least transmits:
the instantaneous voltage from the signal monitor to the oscilloscope interface;
control signals from the oscilloscope interface to at least one of the signal monitor or the signal generator; and
electrical supply power from the oscilloscope interface to at least one of the signal monitor or the signal generator.

16. The active time-domain reflectometry measurement probe according to claim 1, further comprising a housing that comprises the at least one oscilloscope interface, the respective measurement interfaces, the signal generator, and the signal monitor.

17. A measurement application system comprising:
a real-time oscilloscope; and
an active time-domain reflectometry measurement probe coupled to the real-time oscilloscope, wherein the active time-domain reflectometry measurement probe comprises:
at least one oscilloscope interface for coupling to a real-time oscilloscope;
a measurement interface for each oscilloscope interface, wherein each measurement interface is coupled to the respective oscilloscope interface and is configured to couple to a device under test;
a signal generator coupled to each measurement interface, wherein the signal generator is configured to generate a test signal and provide the test signal to each measurement interface; and
a signal monitor configured to transmit an instantaneous voltage at each one of the measurement interfaces to the respective oscilloscope interface.

18. The measurement application system of claim 17, wherein the active time-domain reflectometry measurement probe comprises a housing, separate from the real-time oscilloscope, that includes the at least one oscilloscope interface, the respective measurement interfaces, the signal generator, and the signal monitor.

19. The measurement application system of claim 17, wherein the oscilloscope interface comprises at least one coaxial connector.

20. The measurement application system of claim 17, wherein the oscilloscope interface comprises an active probe interface configured to transmit at least one of: at least one measurement signal, at least one digital data signal, or electrical supply power,
wherein the active probe interface is configured to receive electrical supply power and supply the at least on signal generator with the electrical supply power.
